(19) United States
(12) Patent Application Publication
(10) Pub. No.: US 2022/0186363 A1
(43) Pub. Date: Jun. 16, 2022

(54) DIAMOND-LIKE CARBON COATINGS AND METHODS OF MAKING THE SAME

(71) Applicant: Techroko Inc., Campbell, CA (US)

(72) Inventors: Kuo Hsing Hwang, San Jose, CA (US); Xing Lu, Campbell, CA (US)

(21) Appl. No.: 17/187,012

(22) Filed: Feb. 26, 2021

Related U.S. Application Data
(60) Provisional application No. 63/124,127, filed on Dec. 11, 2020.

(51) Int. Cl. C23C 16/27; C23C 16/50; C23C 16/56

(52) U.S. Cl. CPC C23C 16/27; H01L 21/02115; C23C 16/56; C23C 16/50

(57) ABSTRACT

In accordance with some embodiments of the present disclosure, a diamond-like carbon coating is provided. The diamond-like carbon coating may include a substrate and a diamond-like carbon film formed on the substrate. The diamond-like carbon film may include a plurality of layers of diamond-like carbon. A first layer of diamond-like carbon in the diamond-like carbon film is softer than a second layer of diamond-like carbon in the diamond-like carbon film. In some embodiments, the diamond-like carbon coating may further include a barrier layer and/or a UV protection layer formed between the substrate and the diamond-like carbon film. In some embodiments, the diamond-like carbon coating may further include a hydrophobic layer formed on the diamond-like carbon film. The diamond-like carbon coating is optically transparent.

### CROSS-REFERENCE TO RELATED APPLICATION

This application claims the benefit of U.S. Provisional Patent Application No. 63/124,127, filed Dec. 11, 2020, which is hereby incorporated by reference herein in its entirety.

### TECHNICAL FIELD

The implementations of the disclosure relate generally to forming coatings on substrates and, more specifically, to diamond-like carbon coatings and methods of making the same.

### BACKGROUND

Diamond-like carbon (DLC) may refer to amorphous carbon materials that may display certain typical properties of diamond. DLC may include sp² and sp³ bonds of carbon atoms. DLC may be applied as coatings to other materials to achieve desirable optical or mechanical properties, such as high hardness, high wear resistance, or desired durability. However, existing DLC coatings may have limited applications due to conflicts among the optical and mechanical properties. For example, existing DLC coatings of high hardness typically present high compressive stress and are not suitable for high wear resistance applications due to their limited film thicknesses. As another example, optical durability applications typically require films of a certain thickness (e.g., a thickness of 1-10 micrometers). However, existing DLC coatings of such thickness may be brown or black and are thus not suitable for such optical durability applications. As a further example, existing DLC coatings with high hardness may be electrically insulated.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In accordance with some embodiments of the present disclosure, a substrate and a diamond-like carbon film formed on the substrate. The diamond-like carbon film includes a plurality of layers of diamond-like carbon that includes a first layer of diamond-like carbon and a second layer of diamond-like carbon. The first layer of diamond-like carbon is softer than the second layer of diamond-like carbon.

The diamond-like carbon coating is optically transparent.

In some embodiments, the diamond-like carbon coating further includes a barrier layer formed on the substrate. The barrier layer is positioned between the substrate and the diamond-like carbon film. In some embodiments, the barrier layer includes at least one of SiO₂ or Al₂O₃. In some embodiments, the barrier layer is optically transparent.

In some embodiments, the barrier layer includes a first layer of SiOₓC_{y} and a second layer of SiOₓC_{y}, and wherein the first layer of SiOₓC_{y} is softer than the second layer of SiOₓC_{y}.

In some embodiments, the diamond-like carbon coating further includes an ultraviolet (UV) protection layer formed on the substrate. In some embodiments, the UV protection layer is electrically conductive.

In some embodiments, the UV protection layer is positioned between the substrate layer and the diamond-like carbon film.

In some embodiments, the UV protection layer is positioned between the barrier layer and the diamond-like carbon film.

In some embodiments, the UV protection layer comprises a crystalline layer of at least of one of ZnO, Al-doped ZnO, or TiO₂.

In some embodiments, the UV protection layer includes a transition layer positioned between the UV blocking layer and the diamond-like carbon film.

In some embodiments, the diamond-like carbon coating further includes a hydrophobic layer formed on the diamond-like carbon film.

In accordance with one or more aspects of the present disclosure, methods for fabricating a diamond-like carbon coating are provided. The methods include forming, on a substrate, a diamond-like carbon film on the substrate. Forming the diamond-like carbon film includes forming a plurality of layers of diamond-like carbon, wherein the plurality of layers of diamond-like carbon materials comprises a first layer of diamond-like carbon materials and a second layer of diamond-like carbon materials, wherein the first layer of diamond-like carbon materials is softer than the second layer of diamond-like carbon materials, and wherein the diamond-like carbon coating is optically transparent.

In some embodiments, forming the plurality of layers of diamond-like carbon includes depositing an initial layer of DLC; etching the initial layer of DLC to produce an etched initial layer of DLC; and depositing a subsequent layer of DLC on the etched initial layer of DLC.

In some embodiments, the methods further include forming a barrier layer on the substrate, wherein forming the barrier layer includes depositing a layer of at least one of SiO₂, Al₂O₃, or SiOₓC_{y}.

In some embodiments, forming the barrier layer includes forming a first layer of SiOₓC_{y} and a second layer of SiOₓC_{y}, and wherein the first layer of SiOₓC_{y} is softer than the second layer of SiOₓC_{y}.

In some embodiments, the methods further include forming an ultraviolet (UV) protection layer on the substrate, wherein the UV protection layer is electrically conductive.

In some embodiments, forming the UV protection layer includes forming a crystalline layer of at least of one of ZnO, Al-doped ZnO, or TiO₂.

In some embodiments, forming the UV protection layer includes forming a transition layer positioned on the UV blocking layer.

In some embodiments, the methods further include growing the diamond-like carbon coating to a thickness greater than 100 nm.

In some embodiments, the methods further include growing the diamond-like carbon coating to a thickness of the diamond-like carbon coating is greater than 1 micrometer.

In some embodiments, the methods further include forming a hydrophobic layer formed on the diamond-like carbon film.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIGS. 1A, 1B, 2A, 2B, 2C, 2D, 3A, 3B, and 3C are schematic diagrams depicting structures associated with a process for producing DLC coatings in accordance with some embodiments of the present disclosure.

FIGS. 4, 5A, 5B, 6, and 7 are flow diagrams illustrating example methods for fabricating DLC coatings according to some embodiments of the disclosure.

FIGS. 8A and 8B depict examples of systems for fabricating DLC coatings in accordance with some embodiments of the present disclosure.

FIGS. 9A, 9B, and 9C are schematic diagrams depicting examples of DLC coatings according to some embodiments of the present disclosure.

FIGS. 9D and 9E are schematic diagrams depicting example barrier layers according to some embodiments of the present disclosure.

FIG. 10 is a schematic diagram illustrating an example of a dual-frequency capacitively coupled plasma (CCP) system for fabricating DLC coatings in accordance with some embodiments of the present disclosure.

FIG. 11 is a schematic diagram illustrating an example of a plasma-enhanced chemical vapor deposition (PECVD) system for fabricating DLC coatings in accordance with some embodiments of the present disclosure.

### DETAILED DESCRIPTION

Aspects of the disclosure provide for diamond-like carbon coatings and mechanisms for making the diamond-like carbon coatings. As referred to herein, diamond-like carbon (DLC) materials may refer to amorphous carbon materials that may display certain typical properties of diamond. DLC materials may include sp² and sp³ bonds of carbon atoms.

The DLC coatings fabricated in accordance with the present disclosure may present multiple desired optical properties and/or mechanical properties, such as electrical conductivity, ultraviolet (UV) protection capacity, optical transparency, mechanical durability, anti-smudge capability, etc. In some embodiments, the hardness of a DLC coating fabricated in accordance with the present disclosure may be about 7H-9H measured using a pencil hardness test. In some embodiments, the hardness of a DLC coating fabricated in accordance with the present disclosure may be about 10-20 GPa measured using a nano-indentation test method. In some embodiments, a thickness of the DLC coating may be between about 2 nm and about 2000 nm.

The DLC coatings may have any suitable thickness without compromising their optical and/or mechanical properties. The DLC coatings may be used to implement various applications, such as display overcoats, screen protectors for mobile phones or other computing devices, eyeglasses, window coatings with defroster capability, decorative glass, building glass, etc.

In some embodiments, a DLC coating may include a substrate and a DLC film. The DLC film may include multiple DLC layers of varying hardness. For example, the DLC film may include one or more soft DLC layers and one or more hard DLC layers alternatively stacked on each other. The soft DLC layer(s) may neutralize mechanical stress and prevent delamination. The DLC film may be optically transparent. In some embodiments, the DLC film with an optical transmission rate of about or greater than 90% for visible light may be regarded as being optically transparent.

In some embodiments, the DLC coating may further include a hydrophobic layer formed on the DLC film. The hydrophobic layer may be and/or include, for example, an anti-smudge coating formed on a surface of the DLC film.

In some embodiments, a barrier layer may be formed between the substrate and the DLC film. The barrier layer may serve as a moisture barrier for the DLC coating and/or enhance adherence between the substrate and layers formed on the substrate (e.g., the DLC film). In some embodiments, the barrier layer may include one or more layers of SiO₂, A1₂O₃, SiOₓC_{y}, etc.

In some embodiments, a UV protection layer may be formed between the substrate and the DLC film. The UV protection layer may include one or more layers of one or more suitable materials that may prevent the substrate from UV damage, such as ZnO, Al-doped ZnO, TiO₂, etc. The UV protection layer may be optically transparent and electrically conductive. In one implementation, the UV protection layer may be formed on the barrier layer. In another implementation, the DLC coating does not include the barrier layer. In such implementation, the UV protection layer may be formed directly on the substrate.

As will be discussed in greater detail below, one or more components of the DLC coating may be omitted or modified to implement various applications and/or to achieve DLC coatings of various desired optical and mechanical properties. A DLC film is typically a hard compressive film. The desirable properties of DLC may be realized due to numerous types of mismatch between substrates and DLC at the bottom, such as stress mismatch, thermal expansion mismatch, chemical bonding mismatch. The desirable DLC properties may be utilized by multi-layers stress cancellation and hardness gradient. For example, hydrophobicity or lipophobicity may be achieved by making the surface of the DLC coating completely passivated and thus nonstick.

An existing screen protector typically includes a tempered glass of a certain thickness to achieve desired hardness (e.g., 9H in the pencil scale). Such tempered glass screen protector may easily crack if the surface or a top portion of the tempered glass cracks, resulting in damages to the screen below the tempered glass. A DLC coating in accordance with the present disclosure may be fabricated on a flexible substrate (e.g., a plastic substrate) while presenting high hardness. As such, any hard impact on the surface of the DLC coating will not crack through the DLC coating. The DLC coating may be used as a durable screen protector.

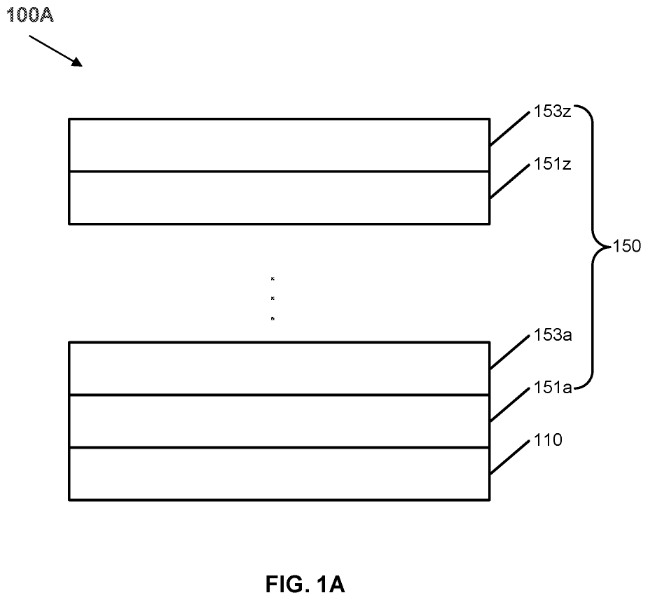

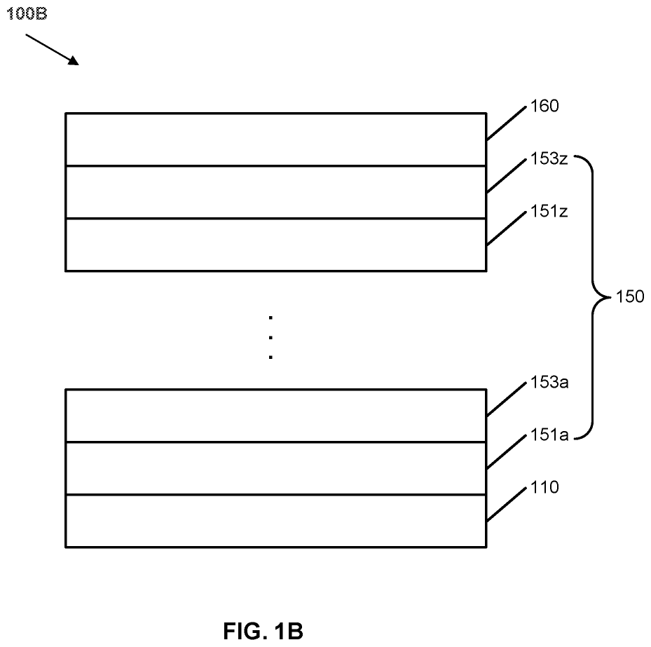

FIGS. 1A, 1B, 2A, 2B, 2C, 2D, 3A, 3B, and 3C illustrate structures associated with processes for fabricating diamond-like carbon (DLC) coatings in accordance with some embodiments of the present disclosure.

Turning to FIG. 1A, a substrate 110 may be provided. Substrate 110 may include any suitable material that can provide a desirable original pattern, color, and/or layout of circuitry to be seen through for the DLC coating to be fabricated. For example, substrate 110 may include one or more plastic materials, glass, wood, textiles, semiconductor materials (e.g., silicon), smart windows, displays (e.g., OLED displays), etc.

A DLC film 150 may be formed on substrate 110 to form a DLC coating 100A. DLC film 150 may be optically transparent (e.g., with an optical transmission rate of about or greater than 96% for visible light). In some embodiments, DLC film 150 may present an optical transmission rate of about 90%-99% for visible light. In some embodiments, a DLC film with an optical transmission rate of about or greater than 90% for visible light may be regarded as being optically transparent. DLC film 150 may include a multi-layer DLC structure including a plurality of DLC layers. Each of the DLC layers may include a layer of one or more amorphous carbon materials with sp² and sp³ bonds of carbon atoms. The DLC layers may have various hardness. For example, DLC film 150 may include one or more soft DLC layers 151a-151z and one or more hard DLC layers 153a-153z alternatively stacked on each other. As such, soft DLC layers 151a-151z and hard DLC layers 153a-153z form a plurality of pairs of a soft DLC layer and a hard DLC layer, wherein the hard DLC layer has higher hardness than the soft DLC layer. More particularly, for example, DLC film 150 may include a pair of a soft DLC layer 151a and a hard DLC layer 153a. Soft DLC layer 151a may be softer than hard DLC layer 153a. In some embodiments, hard DLC layer 153a may be formed on soft DLC layer 151a so that soft DLC layer 151 may neutralize film stress and/or prevent delamination in the multi-layer structure. DLC film 150 may further include a soft DLC layer 151z and a hard DLC layer 153z. Soft DLC layer 151z may be softer than hard DLC layer 153z. Soft DLC layer 151a may or may not be softer than one or more other soft DLC layers in DLC film 150 (e.g., soft DLC layer 151z). In one implementation, soft DCL layer 151a and soft DLC layer 151z may have the same hardness. In another implementation, soft DCL layer 151a and soft DLC layer 151z have different hardness values. While a certain number of pairs of soft DLC layers and hard DLC layers are illustrated in FIG. 1A, this is merely illustrative. DLC film 150 may include any suitable number of pairs of soft DLC layers and hard DLC layers. For example, DLC film 150 may include a pair of a soft DLC layer and a hard DLC layer in some embodiments.

In some embodiments, a thickness of DLC film 150 may be about a few micrometers. As an example, a heavy-duty application of DLC film 150 may have a thickness of about 5 μm. In some embodiments, a thickness of DLC film 150 may be about a few nanometers (e.g., 15 nm-100 nm). As an example, a thickness of a display screen protection incorporating DLC film 150 may be about 20 nm. In some embodiments, a thickness of DLC film 150 may be about a few hundred nanometers to a few micrometers.

Existing DLC coatings with certain thicknesses (e.g., a thickness greater than 100 nm) are not transparent due to SP₂ bond between carbon and carbon. More particularly, the electrically conductive electron in Pi bond may absorb photons. According to one or more aspects of the present disclosure, one or more DLC layers may be etched using etching gases including fluorine, hydrogen, are/or chlorine to bleach off the brown color (e.g., by either etching off graphitic carbon or passivating Pi bond by supplying F and/or H colors). A transparent DLC coating may be formed by depositing the DLC layer(s) and performing the etching process iteratively.

Turning to FIG. 1B, a hydrophobic layer 160 may be formed on DLC film 150 to form a DLC coating 100B. Hydrophobic layer 160 may include a fluorinated overcoat. In some embodiments, hydrophobic layer 160 may be and/or include one or more anti-smudge coatings with high water contact angle (e.g., 90-120 degrees). A thickness of hydrophobic layer 160 may be about 1 nm to 300 nm in some embodiments. As an example, a thickness of hydrophobic layer 160 of a display screen protector incorporating a DLC coating disclosed herein may be about or greater than 10 nm. In some embodiments, a thickness of the hydrophobic layer may be between about 50 nm and about 100 nm.

In some embodiments, DLC coatings 100A and/or 100B may be used as screen protectors on a display (e.g., a display of a mobile phone or any other computing device). In such embodiments, substrate 110 may be and/or include plastic materials, glass, laminated articles, etc. In some embodiments, a thickness of DLC coating 100A and/or DLC coating 100B may be between about 15 nm and 100 nm. In some embodiments, a thickness of DLC coating 100A and/or DLC coating 100B may be between about a few hundred nanometers and a few micrometers.

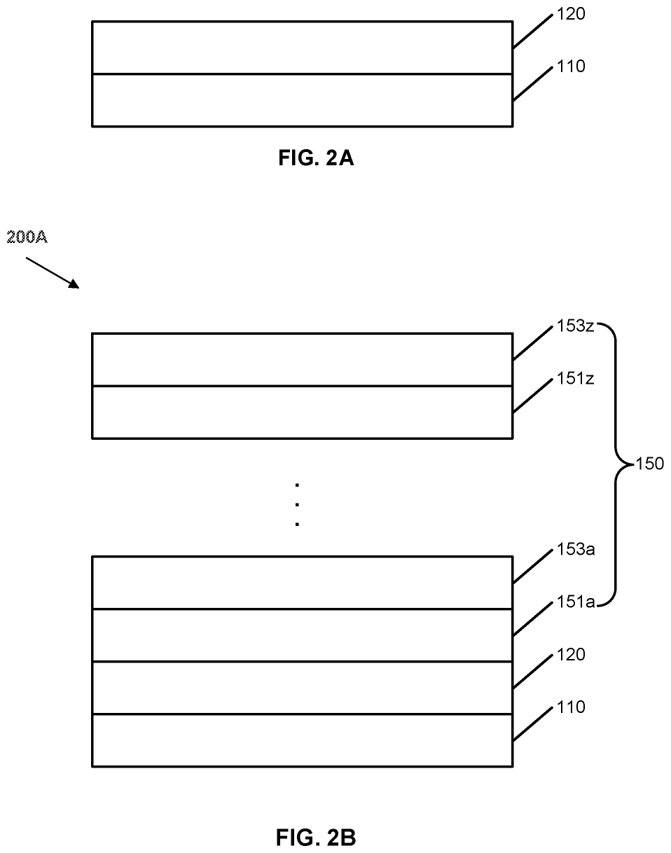

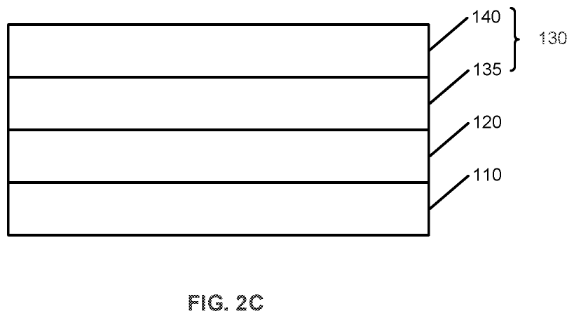

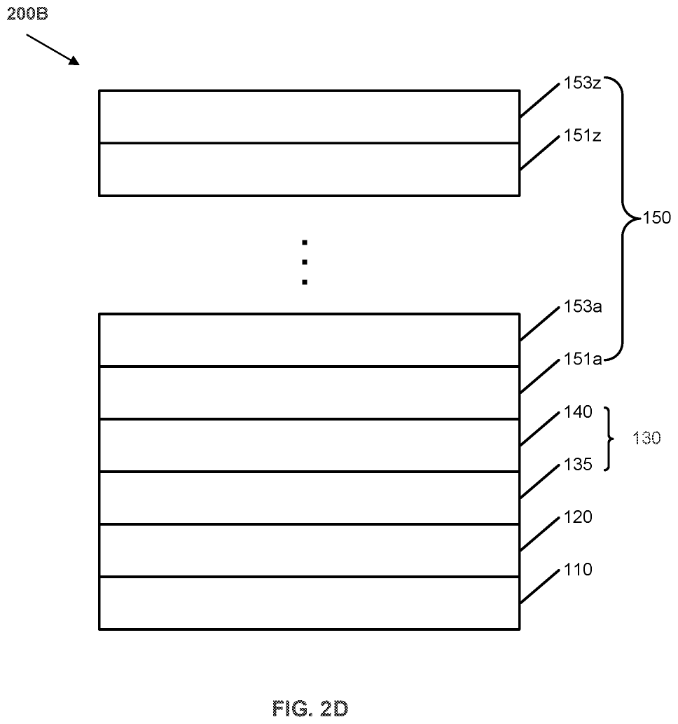

In some embodiments, one or more barrier layers may be deposited between substrate 110 and DLC film 150. The barrier layers may protect substrate 111 and/or the DLC coating from moisture, ultraviolet (UV) radiation, etc. For example, as shown in FIG. 2A, a barrier layer 120 may be formed on substrate 110. Barrier layer 120 is optical transparent in some embodiments. A thickness of barrier layer 120 may be between about a few nanometers and a few micrometers. In some embodiments, a thickness of the barrier layer may be about 20 nm. Barrier layer 120 may prevent moisture from penetrating through substrate 110 and reaching layers formed on substrate 110. Barrier layer 120 may also improve adhesion between one or more layers formed on substrate 110 (e.g., DLC film 150) and substrate 110. Barrier layer 120 may include any suitable material that may implement a moisture barrier and/or an adhesion layer, such as SiO₂, Al₂O₃, SiOₓC_{y}, the like, or a combination of the above.

In some embodiments, barrier layer 120 may include SiO₂ and A1203 deposited on substrate 110 alternatively. For example, barrier layer 120 may include a plurality of layers of SiO₂ and Al₂O₃ alternatively stacked on each other (not shown), such as a first layer of SiO₂, a first layer of Al₂O₃ formed on the first layer of SiO₂, a second layer of SiO₂ formed on the first layer of Al₂O₃, a second layer of Al₂O₃ formed on the second layer of SiO₂, etc.

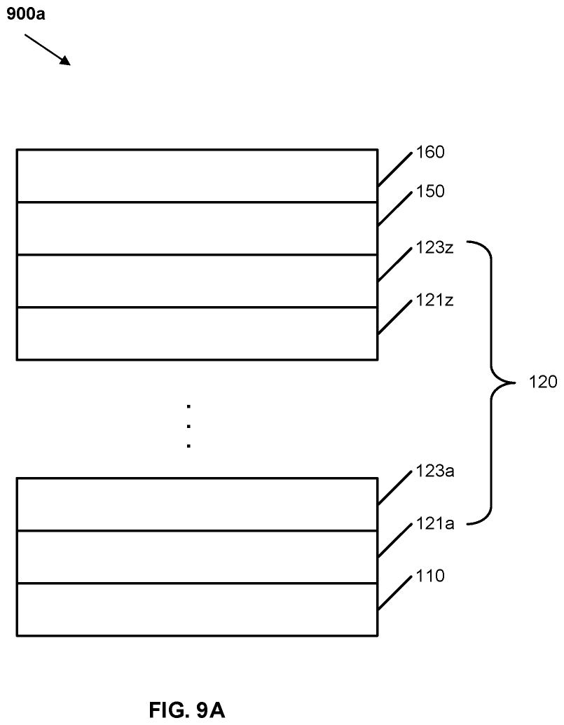

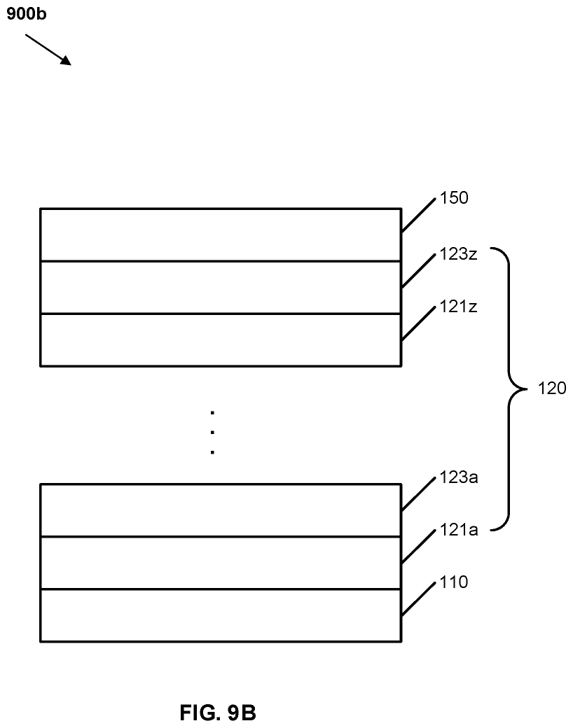

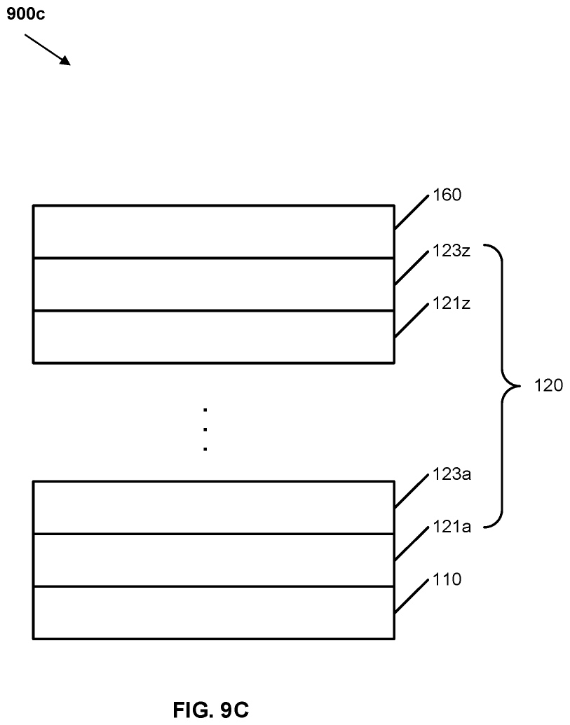

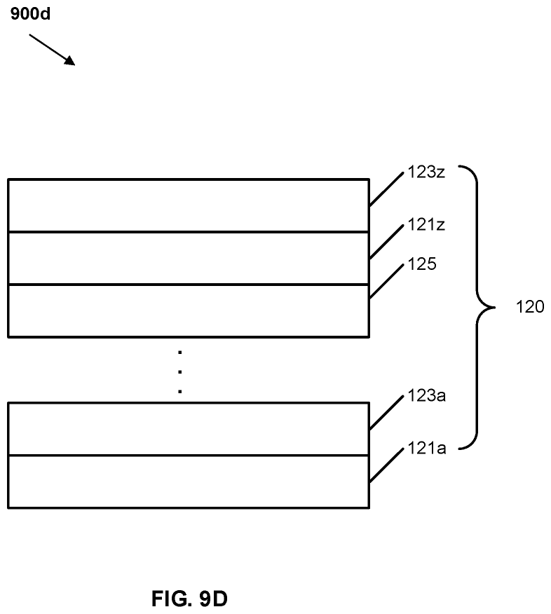

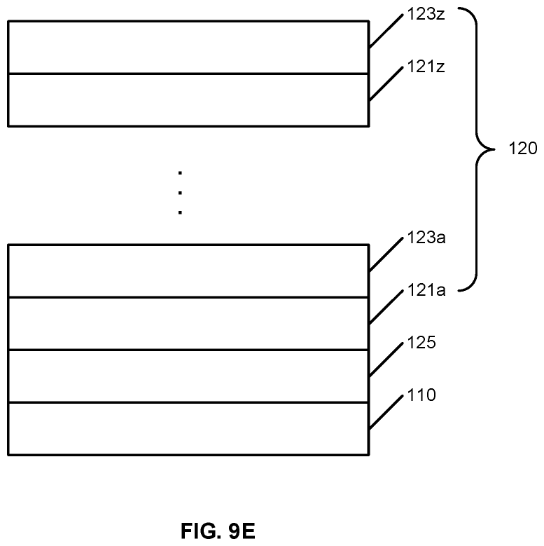

In some embodiments, barrier layer 120 may include one or more layers of SiOₓC_{y}. For example, as will be discussed in greater detail in conjunction with FIGS. 9A-9E, the barrier layer may include a plurality of SiOₓC_{y} layers of varying hardness, such as a plurality of soft SiOₓC_{y} layers and hard SiOₓC_{y} layers stacked alternatively on each other. In some embodiments, barrier layer 120 may further include a plastic sheet positioned between two SiOₓC_{y} layers.

In some embodiments, as shown in FIG. 2B, DLC film 150 may be formed on barrier layer 120 to form a DLC coating 200A. As such, barrier layer 120 is positioned between substrate 110 and DLC film 150.

The formation of barrier layer 120 on substrate 110 may enhance the hardness of the DLC coating. For example, substrate 110 may have a first hardness value, while the DLC coating 200A including substrate 110 and barrier layer 120 may have a second hardness value that is greater than the first hardness value. In one implementation, substrate 110 may include polycarbonate (PC) and may have a hardness of about or lower than 1H in pencil hardness scale. In another implementation, substrate 110 may include laminated PC and may have a hardness of about or lower than 3H in pencil hardness scale. Barrier layer 120 including SiOₓC_{y} and/or Si₃N₄ may be deposited on substrate 110 to enhance the hardness of the DLC coating (e.g., to a hardness of about or higher than 3H in pencil hardness scale). In some embodiments, the thickness of barrier layer 120 may be between about 5 μm and 8 μm. The formation of DLC film 150 on barrier layer 120 may further enhance the hardness of the DLC coating (e.g., up to 7H-9H in the pencil hardness scale).

In some embodiments, as shown in FIG. 2C, an ultraviolet (UV) protection layer 130 may be formed on substrate 110 and/or barrier layer 120 to prevent substrate 110 from being exposed to UV and/or to keep the original color features of the components of the DLC coating. In some embodiments, UV protection layer 130 may block about or at least 90% UV radiation. In some embodiments, a thickness of UV protection layer 130 may be about 200 nm. UV protection layer 130 may be optically transparent and electrically conductive.

UV protection layer 130 may include one or more layers of suitable materials that may block UV radiation. For example, UV protection layer 130 may include a UV blocking layer 135 comprising one or more crystalline layers of one or more materials that may prevent one or more portions of UV radiation to which the DLC coating is exposed from perpetrating into the DLC coating. Examples of the materials include Al-doped ZnO, ZnO, TiO₂, etc. In some embodiments, UV blocking layer 135 may include one or more layers of ZnO and TiO₂. In some embodiments, UV blocking layer 135 may include layers of ZnO and TiO₂ alternatively stacked on each other (not shown), such as a first layer of ZnO, a first layer of TiO₂ formed on the first layer of ZnO, a second layer of ZnO formed on the first layer of TiO₂, a second layer of TiO₂ formed on the second layer of ZnO, etc.

In some embodiments, one or more portions of UV blocking layer 135 may be electrically conductive. For example, UV blocking layer 135 may include one or more layers of Al-doped ZnO of a suitable thickness (e.g., about 100 nm to 500 nm) to connect a power source (e.g., a DC power source) to the DLC coating. As such, UV protection layer 130 may provide both UV blocking and electrical conductivity functionalities.

In some embodiments, UV protection layer 130 may further include a transition layer 140 formed on UV blocking layer 135. Transition layer 140 may serve as a transition from the crystalline layers in UV blocking layer 135 to DLC film 150 that includes amorphous materials. Transition layer 140 may further enhance adhesion of DLC film 150 on UV protection layer 130 and/or UV blocking layer 135. Transition layer 140 may include SiO₂, Al₂O₃, the like, or a combination of the above. In some embodiments, transition layer 140 may include layers of SiO₂ and A1₂O₃ alternatively stacked on each other (not shown), such as a first layer of SiO₂, a first layer of Al₂O₃ formed on the first layer of SiO₂, a second layer of SiO₂ formed on the first layer of Al₂O₃, a second layer of Al₂O₃ formed on the second layer of SiO₂, etc. The ZnO film may include perpendicular ZnO rods, while DLC is amorphous. The transitional layer may change the growth orientation and help DLC adhere better on layer below. Chemically, carbon adhere well onto silicon or SiOxCy. A thickness of transition layer 140 may be about a few nanometers to a few micrometers (e.g., a thickness of about or greater than 2 nm).

In some embodiments, as shown in FIG. 2D, DLC film 150 may be formed on UV protection layer 130 to form a DLC coating 200B. As such, DLC coating 200B includes substrate 110, barrier layer 120, UV protection layer 130, and DLC film 150. As shown, UV protection layer 130 is positioned between substrate 110 and DLC film 150. DLC coating 200B may be optically transparent and electrically conductive.

In some embodiments, DLC coatings 100A, 100B, 200A, and/or 200B may be used as screen protectors on a display (e.g., a display of a mobile phone or any other computing device). In such embodiments, substrate 110 may be and/or include plastic materials, glass, laminated articles, etc. In some embodiments, a thickness of each of DLC coatings 100A, 100B, 200A, and/or 200B may be between a few hundred nanometers and a few micrometers. In some embodiments, a thickness of each of DLC coatings 100A, 100B, 200A, and/or 200B may be between about 15 nm and about 100 nm.

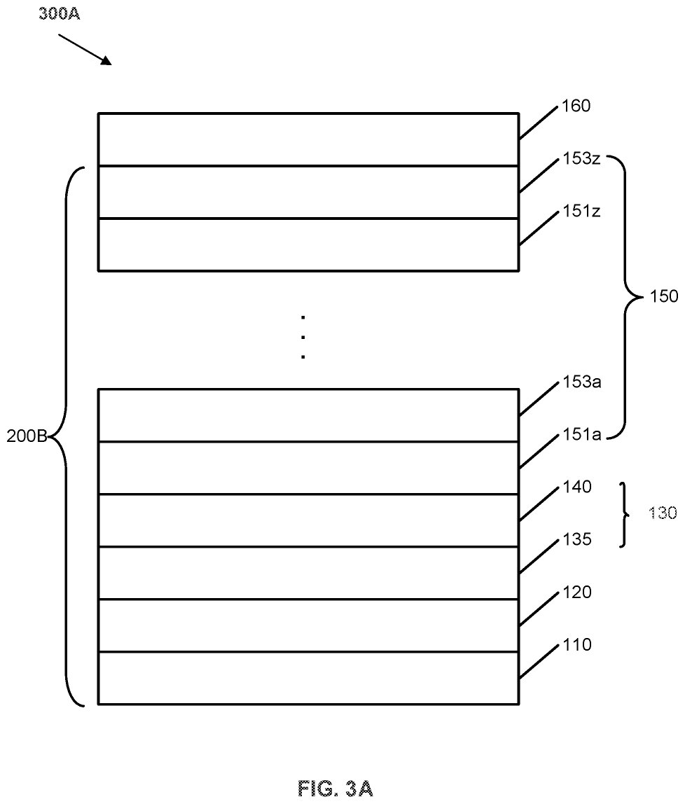

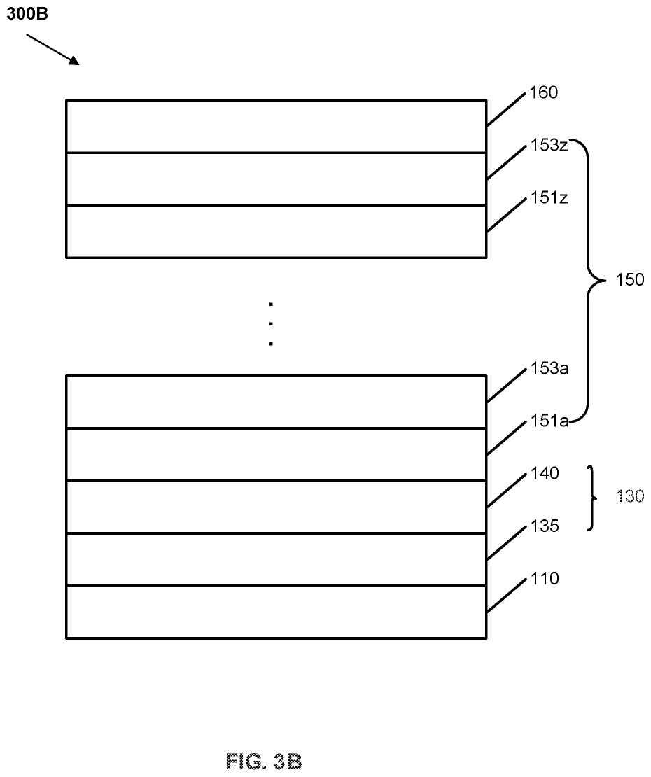

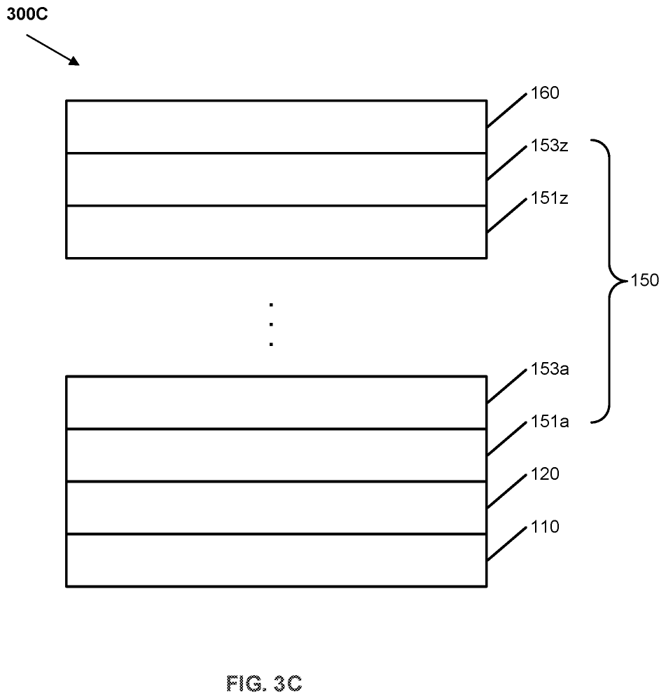

In some embodiments, as shown in FIG. 3A, hydrophobic layer 160 may be formed on DLC coating 200B to form a DLC coating 300A. DLC coating 300A may include substrate 110, barrier layer 120, UV protection layer 130, DLC film 150, and hydrophobic layer 160.

In some embodiments, barrier layer 120 may be omitted from DLC coating 300A. For example, as illustrated in FIG. 3B, DLC coating 300B may include substrate 110, UV protection layer 130, DLC film 150, and hydrophobic layer 160. Each layer and/or component of DLC coatings 300A and 300B may be optically transparent. As such, DLC coatings 300A and/or 300B may be optically transparent.

As described above, one or more portions of UV blocking layer 135 may be electrically conductive. For example, UV blocking layer 135 may include one or more layers of Al-doped ZnO of a suitable thickness to connect a power source (e.g., a DC power source). Each of DLC coatings 300A and 300B may be electrically conductive and may be used in applications requiring electrical conductivity, such as window coatings with both UV blocking and defroster functions.

In some embodiments, UV protection layer 130 may be omitted from DLC coating 300A. For example, as illustrated in FIG. 3C, DLC coating 300C may include substrate 110, barrier layer 120, DLC film 150, and hydrophobic layer 160. Each layer and/or component of DLC coating 300C may be optically transparent. As such, DLC coating 300C may be optically transparent.

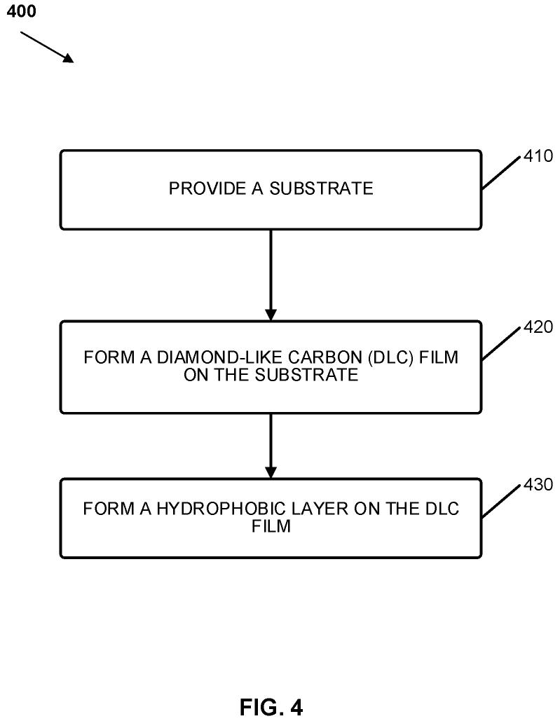

FIG. 4 is a flow diagram illustrating an example 400 of a method for fabricating a DLC coating according to some embodiments of the disclosure. Method 400 may be performed to fabricate DLC coatings 100A and/or 100B of FIGS. 1A-1B in some embodiments.

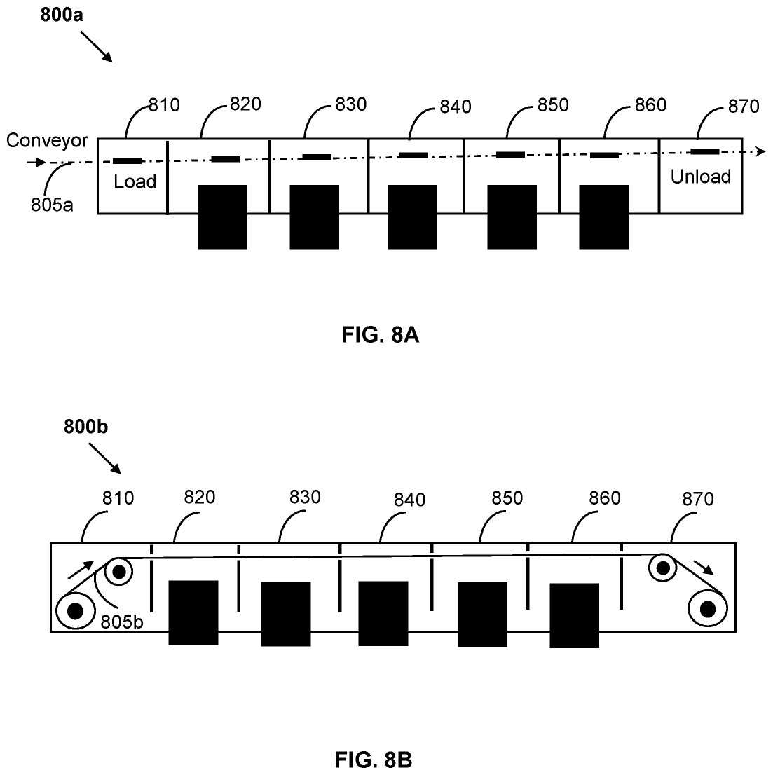

Method 400 may start at block 410, where a substrate may be provided. The substrate may include, for example, one or more plastic materials, glass, wood, textiles, semiconductor materials (e.g., silicon). The substrate may be and/or include substrate 110 as described in connection FIG. 1A above. In some embodiments, providing the substrate may involve loading the substrate into a static machine (e.g., a PECVD system), a system 800a or 800b of FIGS. 8A-8B, or any other suitable system that may be used to fabricate a DLC coating.

At block 420, a DLC film may be formed on the substrate. The DLC film may be optically transparent. In some embodiments, the DLC film may be and/or include the DLC film 150 as described in connection with FIGS. 1A-1B above. Forming the DLC film may include forming a multi-layer DLC structure comprising a plurality of DLC layers of varing hardness, such as a first layer of DLC and a second layer DLC formed on the first layer of DLC. The first layer of DLC may be softer than the second layer DLC. In some embodiments, forming the DLC film may further include forming a third layer of DLC. The third layer of DLC may be softer than the second layer of DLC. In some embodiments, forming the DLC film may further include forming a fourth layer of DLC. The third layer of DLC may be softer than the fourth layer of DLC.

Each of the DLC layers may be formed by alternatively performing a deposition process and an etching process in an iterative manner until a desired thickness is achieved. For example, a DLC layer of the multi-layer DLC structure may be formed by depositing an initial DLC layer of using any suitable deposition technique and/or combination of deposition techniques, such as plasma-assisted chemical vapor deposition, ion beam deposition, sputter deposition, radio-frequency (RF) plasma deposition, cathodic arc, etc. The initial DLC layer may be thinner than the DLC layer to be formed. An etching process may then be carried out on a surface of the initial DLC layer to produce an etched initial DLC layer. Performing the etching process on the initial DLC layer may etch weak cc-bonds and break hydrogen bonds, resulting in a widening optical band gap and increasing conductivity activation energy. The deposition process may be repeated after the etching process. For example, DLC may be deposited on the etched initial DLC layer to form a subsequent DLC layer on the initial DLC layer. The subsequent DLC layer may then be etched to produce an etched subsequent DLC layer. The deposition process and the etching process may be performed alternatively as described above until the DLC layer is grown to the desired thickness to obtain optically transparent DLC layers. The hardness of each DLC layer in the DLC film may be achieved by tuning processing conditions in the deposition process and/or the etching process.

In some embodiments, the deposition process may include depositing DLC using inductively coupled plasma (ICP) sources. In some embodiments, the deposition process may be carried out using a radio frequency (RF) ICP source. The power value of the RF generator may be set to about 6 W/cm². During the deposition process, a reactant stream may be supplied to a processing chamber in which the substrate is located. In some embodiments, the reactant stream may include a hydrocarbon precursor gas, such as ethane (C₂H₄). In some embodiments, the reactant stream may be a gas mixture of C₂H₄, argon (Ar), and/or helium (He). The flow rate of C₂H₄ may be about 25 sccm. In some embodiments, the deposition rate may be about 65Å/sec. The processing pressure may be, for example, 3.5 mTorr.

The etching process may be performed using the ICP source used in the deposition process. During the etching process, an etching gas mixture comprising CF₄, CCI₄, CHF₃, Ar, and/or H₂ may be supplied to the processing chamber. The processing pressure may be between about 10 mTorr and about 100 mTorr. In some embodiments, a bias of about 50V may be applied to the substrate during the etching process. The etching process may be carried out for a suitable duration, such as 5-60 seconds. The duration of the etching process may be adapted according to different transmission targets.

In some embodiments, prior to the formation of the DLC film, the substrate may be cleaned using ion implantation methods to promote adhesion between the DLC film and the substrate.

In some embodiments, the surface of the substrate may be treated using a gas mixture comprising Ar, O₂, etc. prior to the formation of the DLC film.

In some embodiments, at block 430, a hydrophobic layer may be formed on the DLC film. The hydrophobic layer may include a fluorinated overcoat. In some embodiments, the hydrophobic layer may be formed by forming one or more coatings comprising fluoropolymer on the DLC film. For example, the DLC coating produced by performing operations depicted in blocks 410 and 420 (e.g., DCL coating 100A of FIG. 1A) may be immersed in a solution containing fluoropolymer (e.g., fluoropolymer dissolved in an ether, such as tetrahydrofuran). A desirable thickness of the hydrophobic layer may be achieved by controlling the concentration of fluoropolymer in the solution and/or the duration of the immersion of the DLC coating in the solution containing fluoropolymer. In some embodiments, block 430 may be omitted to produce a DCL coating including a multi-layer DLC structure (e.g., the DCL coating 100A of FIG. 1A).

In some embodiments, forming the hydrophobic layer may involve depositing one or more fluoropolymer films by PECVD using octafluorocyclobutane (c-C₄F₈) or any other suitable precursor gas. In some embodiments, Ar or He may be used as performance enhancement gas in the PECVD process. The power density may be from about 0.1 w/cm² to about 8 w/cm² in some embodiments.

In some embodiments, forming the hydrophobic layer may involve depositing one or more fluoropolymer films by PECVD using a mixture comprising hexafluoroethane (C₂F₆) and H₂.

In some embodiments, forming the hydrophobic layer may involve forming amorphous fluoropolymer films (e.g., Teflon AF1600, AF2400, etc.). The amorphous fluoropolymer films may be formed using a direct liquid injection (DLI) assisted deposition method, a chemical vapor deposition method, etc. In some embodiments, the hydrophobic layer may be UV cured (e.g., processed using UV irradiation).

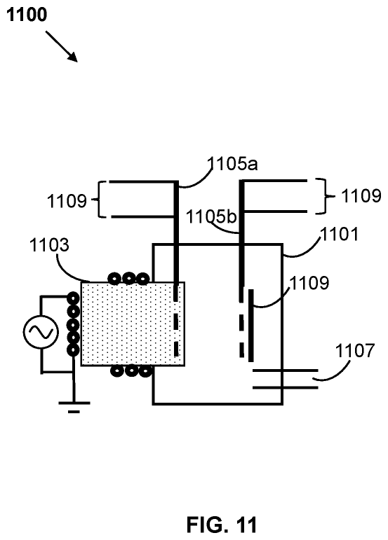

In some embodiments, the DLC coatings described herein may be fabricated using a pass-by machine, such as system 800A and/or 800B as described in connection with FIG. 8. In some embodiments, the DLC coatings described herein may be fabricated using a static machine including a chemical vapor deposition system (e.g., a PECVD reactor or any other suitable reactor), such as PECVD system 1100 of FIG. 11.

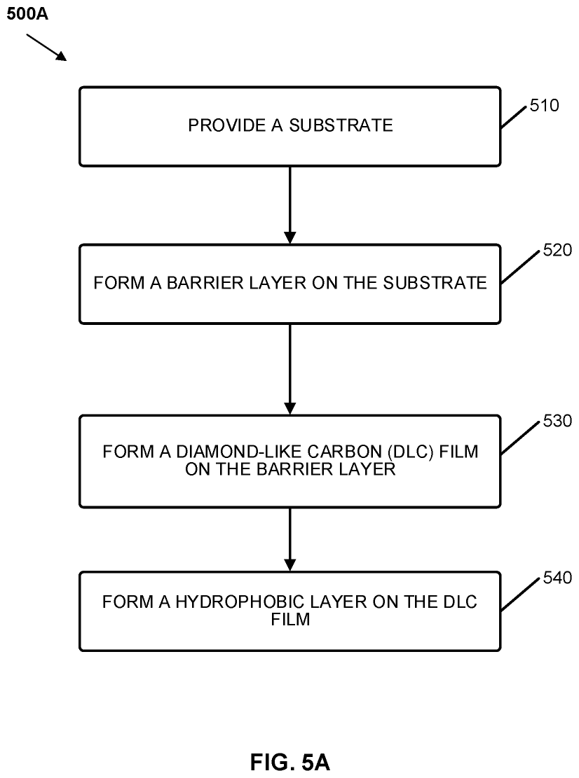

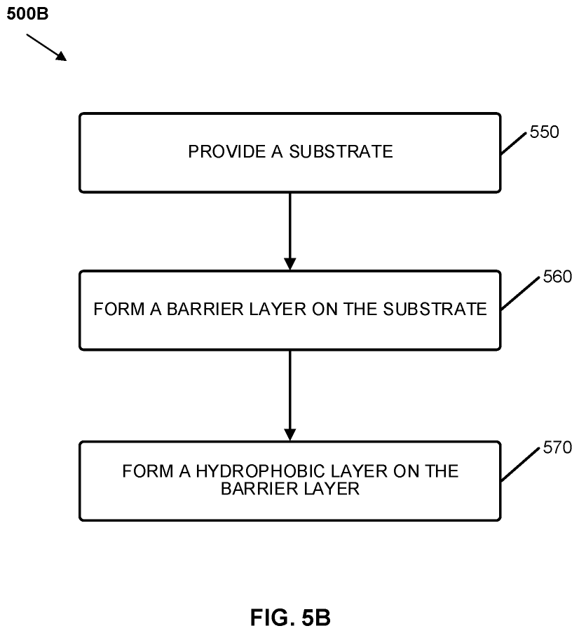

FIGS. 5A and 5B are flow diagrams illustrating examples 500A and 500B of methods for fabricating a DLC coating according to some embodiments of the disclosure. Method 500A may be performed to fabricate a DLC coating 300C of FIG. 3C in some embodiments. Method 500B may be performed to fabricate a DLC coating 900c of FIG. 9C in some embodiments.

Method 500A may begin at block 510, where a substrate is provided. The substrate may be and/or include substrate 110 as described in connection FIG. 1A above.

At block 520, a barrier layer may be formed on the substrate. The barrier layer may prevent moisture from penetrating through the substrate and reaching layers formed on the substrate. The barrier layer may also improve adhesion between layers on the substrate and the substrate. The barrier layer may be and/or include barrier layer 120 as described in connection with FIGS. 2A, 2B, 9A, and/or 9B.

In some embodiments, forming the barrier layer may involve forming one or more layers of SiOₓC_{y}. In some embodiments, forming the barrier layer may involve forming multiple layers of SiOₓC_{y} with varying hardness, such as one or more alternate soft SiOₓC_{y} layers and hard SiOₓC_{y} layers as described in connection with FIGS. 9A-9E. In some embodiments, a first hard SiOₓC_{y} layer may be formed on a first soft SiOₓC_{y} layer. The hardness of the first hard SiOₓC_{y} layer layer may be higher than that of the first soft SiOₓC_{y} layer. A second soft SiOₓC_{y} layer may be formed on the first hard SiOₓC_{y} layer. Any suitable number of soft SiOₓC_{y} layers and hard SiOₓC_{y} layers may be formed to fabricate the barrier layer.

The quality (e.g., the hardness) of the barrier layer may be controlled by adjusting the source power to dissociate the organosilicon precursors and/or the gas ratio of O₂ to the organosilicon precursor(s) (also referred to herein as the “O₂/precursor flow ratio”). For example, forming a SiOₓC_{y} layer using a relatively higher O₂/precursor flow ratio in the PECVD process may deposit more SiO₂ and may thus form a relatively harder film. Forming a SiOₓC_{y} layer using a relatively lower O₂/precursor flow ratio in the PECVD process may result in the formation of a film containing methyl and end up having SiOₓC_{y}. The values of x and y and the hardness of the film may be controlled by adjusting the volume of O₂ and/or the O₂/precursor flow ratio in the PECVD process. For example, using a relatively higher O₂/precursor flow ratio in the PECVD process may deposit SiOₓC_{y} with a relatively greater value of x and a relatively lower value of y. Using a relatively lower O₂/precursor flow ratio in the PECVD process may deposit SiOₓC_{y} with a relatively greater value of y and a relatively lower value of x.

In some embodiments, forming the barrier layer may involve forming one or more layers of SiO₂ and/or one or more layers of Al₂O₃. In some embodiments, a plurality of layers of SiO₂ and Al₂O₃ may be formed alternatively (e.g., a first layer of SiO₂, a first layer of Al₂O₃ formed on the first layer of SiO₂, a second layer of SiO₂ formed on the first layer of Al₂O₃, a second layer of Al₂O₃ formed on the second layer of SiO₂, etc.).

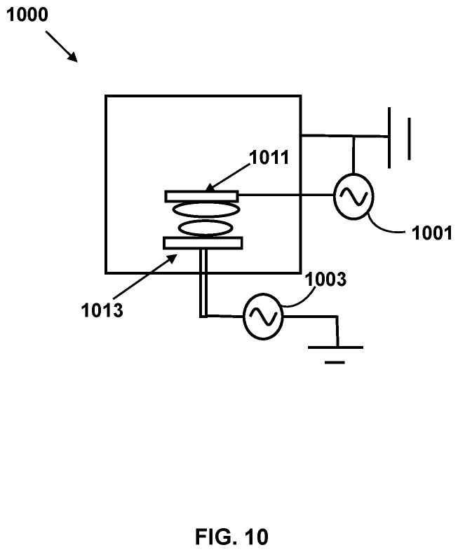

In some embodiments, the barrier layer may be formed utilizing one or more chemical vapor deposition techniques, such as Plasma Enhanced Chemical Vapor Deposition (PECVD) techniques. In some embodiments, the barrier layer may be formed using a suitable plasma source (e.g., a capacitive coupled plasma (CCP) source, an inductively coupled plasma (ICP) source, an RF ICP, hollow cathode, etc.) with precursors comprising organosilicon compounds (e.g., hexamethyldisiloxane (HMDSO), octamethylcyclotetrasiloxane (OMCTS)) in plasma gas comprising O₂, Ar, He, etc. In some embodiments, the barrier layer may be formed using a dual-frequency CCP source comprising multi-frequency radio frequency sources (e.g., system 1000 as described in connection with FIG. 10).

In some embodiments, the barrier layer may be formed using one or more suitable sputtering methods. For example, forming the barrier layer may involve radio frequency (RF) magnetron sputtering of SiO₂ and/or Al₂O₃ to form one or more layers of SiO₂ and/or one or more layers of Al₂O₃. As a more particular example, SiO₂ may be deposited using an RF magnetron sputtering method in a gas mixture of oxygen and argon at a suitable processing pressure (e.g., 2 mTorr). In some embodiments, the gas mixture may further include He and/or H₂. A gas volume ratio of oxygen to argon may be 1/9 in some embodiments. An RF power of about 1500 W may be used to sputtering SiO₂ in some embodiments. The barrier layer may be deposited at a deposition rate lower than 3 Å/sec in some embodiments. In some embodiments, SiO₂ may be deposit using a sputtering target including boron-doped Si. The target can be sputtered using direct current (DC) power supplies or any other suitable power supply. The barrier layer may be deposited at a deposition rate higher than 10 Å/sec.

In some embodiments, the surface of the substrate may be treated using a gas mixture including one or more of Ar, O₂, etc. prior to the formation of the barrier layer.

At block 530, a DLC film may be formed on the barrier layer. Forming the DLC film may include forming a multi-layer DLC structure comprising a plurality of DLC layers of various hardness, such as the DLC film 150 of FIGS. 1A-3B. In some embodiments, the DLC film may be formed by performing one or more operations as described in connection with block 420 of FIG. 4 above. In some embodiments, forming the DLC film may include depositing DLC using an ICP source from a gas mixture comprising SiH₄ and C₂H₄.

In some embodiments, at block 540, a hydrophobic layer may be formed on the DLC film. The hydrophobic layer may include a fluorinated overcoat. In some embodiments, the hydrophobic layer may be formed by forming one or more coatings comprising fluoropolymer on the DLC film. In some embodiments, the hydrophobic layer may be formed by performing one or more operations as described in connection with block 430 of FIG. 4. In some embodiments, block 540 may be omitted to produce a DLC coating 200A of FIG. 2B.

Method 500B may begin at block 550, where a substrate is provided. The substrate may be and/or include substrate 110 as described in connection FIG. 1A above.

At block 560, a barrier layer may be formed on the substrate. The barrier layer may be formed by performing one or more operations as described in connection with block 520 above.

At block 570, a hydrophobic layer may be formed on the barrier layer. The hydrophobic layer may be formed by performing one or more operations as described in connection with block 430 above.

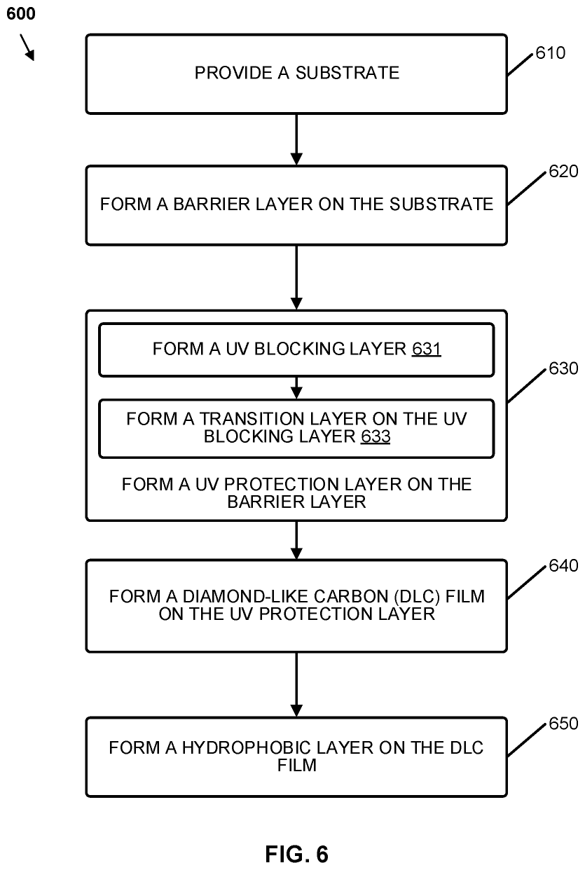

FIG. 6 is a flow diagram illustrating an example 600 of a method for fabricating a DLC coating according to some embodiments of the disclosure. Method 600 may be performed to fabricate a DLC coating 300A of FIG. 3A in some embodiments.

Method 600 may begin at block 610, where a substrate is provided. The substrate may be and/or include substrate 110 as described in connection FIG. 1A above.

At block 620, a barrier layer may be formed on the substrate. The barrier layer may be and/or include the barrier layer 120 as described in connection with FIGS. 2A-2D. The barrier layer may be formed by performing one or more operations as described in connection with block 520 of FIG. 5.

At block 630, a UV protection layer may be formed on the barrier layer. The UV protection layer may prevent the substrate from UV radiation and/or to keep color features of the components of the DLC coating to be formed. The UV protection layer may be optically transparent and electrically conductive. The UV protection layer may be and/or include the UV protection layer 130 of FIGS. 2C-3D above. Forming the UV protection layer may include forming a UV blocking layer as depicted in block 631 and forming a transition layer as depicted in block 633.

At block 631, a UV blocking layer may be formed on the barrier layer. Forming the UV blocking layer may involve forming one or more crystalline layers of Al-doped ZnO, ZnO, TiO₂, etc. In some embodiments, forming the UV blocking layer may involve forming a plurality of layers of ZnO and TiO₂ alternatively stacked on each other (e.g., a first layer of ZnO, a first layer of TiO₂ formed on the first layer of ZnO, a second layer of ZnO formed on the first layer of TiO₂, a second layer of TiO₂ formed on the second layer of ZnO, etc.). For example, forming the UV blocking layer may include forming one or more crystalline layers of ZnO using a suitable RF magnetron sputtering method. The crystalline layers of ZnO may include one or more layers of ZnO oriented along the (002) crystalline direction. As another example, forming the UV blocking layer may include forming one or more crystalline layers of Al-doped ZnO using a suitable DC magnetron sputtering method. Each of the layers of Al-doped ZnO may be a transparent conductive oxide (TCO) layer having suitable electrical conductivity.

At block 633, a transition layer may be formed on the UV blocking layer. The transition layer may include SiO₂, Al₂O₃, the like, or a combination of the above. In some embodiments, transition layer 140 may include layers of SiO₂ and Al₂O₃ alternatively stacked on each other. Forming the transition layer may involve forming one or more layers of SiO₂ and/or one or more layers of Al₂O₃. In some embodiments, a plurality of layers of SiO₂ and Al₂O₃ may be alternatively formed on each other (e.g., a first layer of SiO₂, a first layer of Al₂O₃ formed on the first layer of SiO₂, a second layer of SiO₂ formed on the first layer of Al₂O₃, a second layer of Al₂O₃ formed on the second layer of SiO₂, etc.). The layers of SiO₂ and/or Al₂O₃ may be formed using one or more suitable sputtering methods, such as the sputtering methods described in connection with block 520 of FIG. 5.

At block 640, a DLC film may be formed on the UV protection layer. The DLC film may be formed, for example, by performing one or more operations described in connection with block 420 of FIG. 4.

At block 650, a hydrophobic layer may be formed on the DLC film. The hydrophobic film may be formed, for example, by performing one or more operations described in connection with block 430 of FIG. 4.

In some embodiments, block 650 may be omitted to produce DLC coating 200B of FIG. 2D.

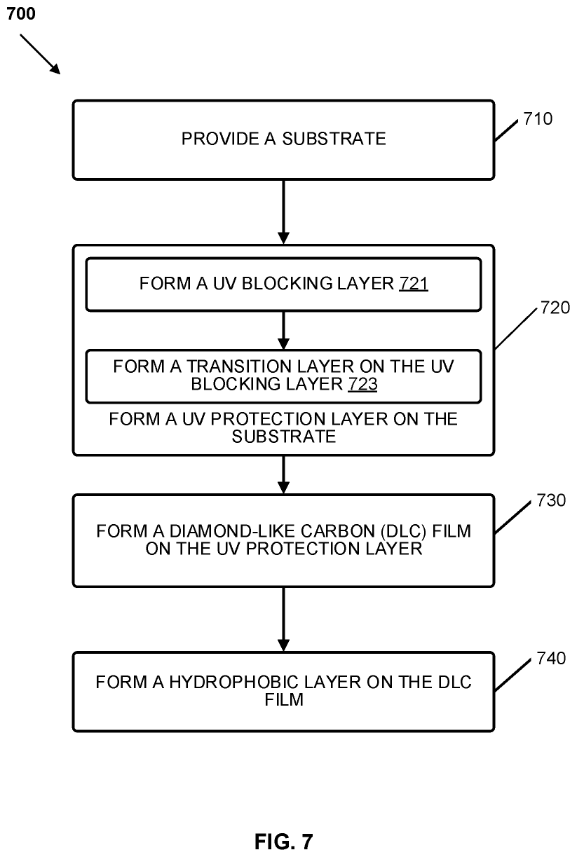

FIG. 7 is a flow diagram illustrating an example 700 of a method for fabricating a DLC coating according to some embodiments of the disclosure. Method 700 may be performed to fabricate a DLC coating 300B of FIG. 3B in some embodiments.

Method 700 may begin at block 710, where a substrate is provided. The substrate may be and/or include substrate 110 as described in connection FIG. 1A above.

At block 720, a UV protection layer may be formed on the substrate. The UV protection layer may prevent the substrate from being exposed to UV and to keep color features of the components of the DLC coating to be formed. The UV protection layer may be and/or include the UV protection layer 130 of FIGS. 2C-3D above. The UV protection layer may be formed by performing one or more operations described in connection with block 630 of FIG. 6. For example, forming the UV protection layer may include forming a UV blocking layer as depicted in block 721 and forming a transition layer as depicted in block 723.

At block 730, a DLC film may be formed on the UV protection layer. The DLC film may be formed, for example, by performing one or more operations described in connection with block 420 of FIG. 4.

At block 740, a hydrophobic layer may be formed on the DLC film. The hydrophobic film may be formed, for example, by performing one or more operations described in connection with block 430 of FIG. 4. In some embodiments, block 740 may be omitted.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

FIGS. 8A and 8B are schematic diagrams depicting examples 800a and 800b of systems that may be used to fabricate DLC coatings in accordance with some embodiments of the present disclosure.

As illustrated, system 800a may include a conveyor 805a and one or more processing stations 810, 820, 830, 840, 850, and 860 for fabricating various components of a DLC coating in accordance one or more aspects of the present disclosure. System 800b may include a conveyor 805b and one or more processing stations 810, 820, 830, 840, 850, and 860 for fabricating various components of a DLC coating in accordance one or more aspects of the present disclosure.

A substrate (e.g., rigid plastic or glass) may be uploaded onto the conveyor 810a or 810b in the processing station 810. The conveyor 805a or 805b may move the substrate to one or more of the processing stations 820, 830, 840, 850 and 860 for processing. Each of the processing stations 820, 830, 840, 850, and 860 may include a reactor in which one or more portions of a DLC coating may be formed. The size of the reactor may be designed based on the size of the substrate that is to be used to form the DLC coating. The conveyor 805a may be suitable for transporting a rigid substrate (e.g., a substrate of rigid plastic materials, a glass substrate, etc.) for fabricating DLC coatings. The conveyor 805b may include one or more pulleys and/or any other suitable mechanisms for conveying a soft substrate (e.g., a substrate of soft plastic materials, a thin glass sheet, etc.) for fabricating DLC coatings.

In the processing station 820, a barrier layer may be formed on the substrate (e.g., by performing one or more operations described in connection with 520 of FIG. 5 and/or block 620 of FIG. 6). In processing station 830, a UV blocking layer may be formed on the substrate and/or the barrier layer (e.g., by performing one or more operations described in connection with 631 of FIG. 6 and/or block 721 of FIG. 7). In processing station 840, a transition layer may be formed (e.g., by performing one or more operations described in connection with 633 of FIG. 6 and/or block 723 of FIG. 7). In processing station 850, a DLC film may be formed (e.g., by performing one or more operations described in connection with block 420 of FIG. 4, block 530 of FIG. 5, and/or block 640 of FIG. 6 and/or block 730 of FIG. 7). In processing station 860, a hydrophobic layer may be formed (e.g., by performing one or more operations described in connection with block 430 of FIG. 4, block 650 of FIG. 6, and/or block 740 of FIG. 7).

In some embodiments, one or more of processing stations 820, 830, 840, and/or 860 may be omitted to implement various embodiments of the present disclosure. For example, a system for performing method 400 of FIG. 4 may include conveyor 810a and/or 810b, processing station 850, and processing station 860. As another example, a system for performing method 500 of FIG. 5 may include conveyor 810a and/or 810b, processing station 820 and 850. As a further example, a system for performing method 600 of FIG. 6 may include conveyor 810a and/or 810b, processing station 820, processing station 830, processing station 840, processing station 850, and processing station 860. As a further example, a system for performing method 600 of FIG. 6 may include conveyor 810a and/or 810b, processing station 830, processing station 840, processing station 850, and processing station 860.

In some embodiments, system 800a and/or 800b may further include a processing station 870 from which the DLC coating may be unloaded.

FIGS. 9A, 9B, and 9C depict example DLC coatings according to some embodiments of the present disclosure. FIGS. 9D and 9E depict examples of a barrier layer according to some embodiments of the present disclosure.

As illustrated in FIG. 9A, DLC coating 900a may include a substrate 110, a barrier layer 120, a DLC film 150, and a hydrophobic layer 160. Barrier layer 120 may include a plurality of layers of SiOₓC_{y} with varying hardness, such as soft SiOₓC_{y} layers 121a, . . . , 121z and hard SiOₓC_{y} layers 123a, . . , 123z that are formed alternatively. More particularly, for example, a first hard SiOₓC_{y} layer 123a may be formed on a first soft SiOₓC_{y} layer 121a. Soft SiOₓC_{y} layer may be softer than hard SiOₓC_{y} layer 123a. A second soft SiOₓC_{y} layer (e.g., SiOₓC_{y} layer 121z) may be formed on the first hard SiOₓC_{y} layer 123a. The second soft SiOₓC_{y} layer may be softer than the first hard SiOₓC_{y} layer 123a. The first soft SiOₓC_{y} layer and the second soft SiOₓC_{y} layer may or may not have the same hardness. In some embodiments, the first SiOₓC_{y} layer and the second SiOₓC_{y} layer have the same hardness. A second hard SiOₓC_{y} layer (e.g., SiOₓC_{y} layer 123z) may be formed on the second soft SiOₓC_{y} layer. The hardness of the second hard SiOₓC_{y} layer may be higher than that of the second soft SiOₓC_{y} layer.

In some embodiments, a thickness of a soft SiOₓC_{y} layer 121a-n may be about 20 nm-200 nm. In some embodiments, a thickness of a hard SiOₓC_{y} layer 123a-n may be about 100 nm-5000 nm. In some embodiments, a thickness of the DLC film 150 is between about 15 nm and about 100 nm.

The soft SiOₓC_{y} layers and the hard SiOₓC_{y} layers alternatively stacked on each other may enhance adhesion between the DLC film and the other component of the DLC coating and the substrate. Residual stress may make the substrate (e.g., a plastic sheet) bend towards its non-coated side. The SiOₓC_{y} layer(s) may enhance the mechanical strength of the substrate and may support the DLC film and/or other component of the DLC coating.

A DLC film 150 may be formed on the barrier layer 120. A hydrophobic layer 160 may be formed on the DLC film 150. In some embodiments, package cardboards (not shown) may sandwich the DLC coating.

In some embodiments, the hydrophobic layer 160 may be omitted. For example, as illustrated in FIG. 9B, DLC coating 900b may include substrate 110, barrier layer 120, and DLC film 150.

In some embodiments, hydrophobic layer 160 may be formed directedly on barrier layer 120. For example, as illustrated in FIG. 9C, DLC coating 900c may include substrate 110, barrier layer 120, and hydrophobic layer 160.

In some embodiments, barrier layer 120 may further include one or more plastic sheets positioned between multiple layers 121a-z and/or 123a-z. For example, as illustrated in FIG. 9D, barrier layer 900d may include a plastic sheet 125 positioned between a hard SiOₓC_{y} layer 121z and a soft SiOₓC_{y} layer 123b. In one implementation, the plastic sheet 125 is in direct contact with soft SiOₓC_{y} layer 123b. In another implementation, the plastic sheet 125 is not in direct contact with soft SiOₓC_{y} layer 123b. For example, one or more layers of SiOₓC_{y} and/or any other suitable material for implementing the functionality of the barrier layer 120 may be positioned between plastic sheet 125 and SiOₓC_{y} layer 123b. As illustrated in FIG. 9E, the plastic sheet 125 may be positioned between the substrate 110 and the barrier layer 120 in some embodiments. DLC film 500 and/or hydrophobic layer 160 may be formed on the barrier layer illustrated in FIGS. 9D-9E.

FIG. 10 is a schematic diagram illustrating an example 1000 of a dual-frequency capacitively coupled plasma (CCP) system for fabricating DLC coatings in accordance with some embodiments of the present disclosure. System 1000 may include a first power source 1001 and a second power source 1003. The first power source 1001 may provide first power of a first frequency to a first electrode 1011 (e.g., the upper electrode) to control plasma density and deposition rate. The second power source 1003 may provide second power of a second frequency to a second electrode 1013 (e.g., the bottom electrode) holding the wafer to control ion bombardment energy/densification and thin film hardness. The first frequency may be higher than the second frequency. As an example, the first frequency may be tens of MHz (e.g., a frequency of about or higher than 13.56 MHz). The second frequency may be hundreds of KHz to a few MHz (e.g., a frequency between about 100 KHz and 2 MHz). The difference between the first frequency and the second frequency may enable interference-free and independent energy control.

FIG. 11 is a schematic diagram illustrating an example 1100 of a plasma-enhanced chemical vapor deposition (PECVD) system for fabricating DLC coatings in accordance with some embodiments of the present disclosure. System 1100 may be used to deposit one or more portions of a DLC coating as described herein.

As shown, system 1100 may include a reactor 1101, a plasma source 1103, electrodes 1105a and 1105b, pump 1107, one or more input ports 1109, and/or any other suitable component.

Plasma source 1103 may include an ICP source, hollow cathode source, etc. Plasma source 1103 may be covered by a shield that may protect the plasma source. Plasma gas may be discharged between parallel electrodes 1105a and 1105b. The plasma gas may include, for example, a gas mixture of one or more of Ar, O₂, He, etc. to form one or more components of a DLC coating. Suitable precursors may be used to form one or more DLC coatings on a substrate 1109 as described herein. For example, a precursor mixture including one or more of HMDSO, OMCTS, C₂H₄, C—C₄F₈, O₂, etc. may be used to form a barrier layer as described herein. The plasma gas and/or the precursors may be provided to reactor 1101 via one or more input ports 1109. Reaction byproducts produced during the fabrication of the DLC coating may be pumped away by the pump 1107.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension. Numeric ranges are inclusive of the numbers defining the range.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A diamond-like carbon coating, comprising:
a substrate; and
a diamond-like carbon film formed on the substrate, wherein the diamond-like carbon film comprises a plurality of layers of diamond-like carbon materials, wherein the plurality of layers of diamond-like carbon materials comprises a first layer of diamond-like carbon and a second layer of diamond-like carbon, wherein the first layer of diamond-like carbon is softer than the second layer of diamond-like carbon, and wherein the diamond-like carbon coating is optically transparent.

2. The diamond-like carbon coating of claim 1, further comprising:
a barrier layer formed on the substrate, wherein the barrier layer is positioned between the substrate and the diamond-like carbon film, and wherein the barrier layer comprises at least one of SiO₂, Al₂O₃, or SiOₓC_{y}.

3. The diamond-like carbon coating of claim 2, wherein the barrier layer comprises a first layer of SiOₓC_{y} and a second layer of SiOₓC_{y}, and wherein the first layer of SiOₓC_{y} is softer than the second layer of SiOₓC_{y}.

4. The diamond-like carbon coating of claim 2, wherein the barrier layer is optically transparent.

5. The diamond-like carbon coating of claim 2, further comprising:
an ultraviolet (UV) protection layer formed on the substrate, wherein the UV protection layer is electrically conductive, and wherein the UV protection layer is positioned between the substrate and the diamond-like carbon film.

6. The diamond-like carbon coating of claim 5, wherein the UV protection layer is positioned between the barrier layer and the diamond-like carbon film.

7. The diamond-like carbon coating of claim 5, wherein the UV protection layer comprises a crystalline layer of at least of one of ZnO, Al-doped ZnO, or TiO₂.

8. The diamond-like carbon coating of claim 7, wherein the UV protection layer comprises a transition layer positioned between the crystalline layer and the diamond-like carbon film.

9. The diamond-like carbon coating of claim 4, wherein a thickness of the diamond-like carbon coating is greater than 1 micrometer.

10. The diamond-like carbon coating of claim 1, further comprising:
a hydrophobic layer formed on the diamond-like carbon film.

11. A method for fabricating a diamond-like carbon coating comprising:
forming, on a substrate, a diamond-like carbon film on the substrate, comprising:
forming a plurality of layers of diamond-like carbon materials, wherein the plurality of layers of diamond-like carbon materials comprises a first layer of diamond-like carbon materials and a second layer of diamond-like carbon materials, wherein the first layer of diamond-like carbon materials is softer than the second layer of diamond-like carbon materials, and wherein the diamond-like carbon coating is optically transparent.

12. The method of claim 11, wherein forming the plurality of layers of diamond-like carbon materials comprises:
depositing an initial layer of DLC;
etching the initial layer of DLC to produce an etched initial layer of DLC; and
depositing a subsequent layer of DLC on the etched initial layer of DLC.

13. The method of claim 11, further comprising:
forming a barrier layer on the substrate, wherein forming the barrier layer comprises depositing a layer of at least one of SiO₂, Al₂O₃, or SiOₓC_{y}.

14. The method of claim 13, wherein forming the barrier layer comprises forming a first layer of SiOₓC_{y} and a second layer of SiOₓC_{y}, and wherein the first layer of SiOₓC_{y} is softer than the second layer of SiOₓC_{y}.

15. The method of claim 13, further comprising:
forming an ultraviolet (UV) protection layer on the substrate, wherein the UV protection layer is electrically conductive.

16. The method of claim 14, wherein the UV protection layer is formed between the barrier layer and the diamond-like carbon film.

17. The method of claim 14, wherein forming the UV protection layer comprises forming a crystalline layer of at least of one of ZnO, Al-doped ZnO, or TiO₂.

18. The method of claim 17, wherein forming the UV protection layer comprises forming a transition layer positioned on the crystalline layer.

19. The method of claim 14, wherein the diamond-like carbon coating is grown to a thickness greater than 100 nm.

20. The method of claim 11, further comprising:
forming a hydrophobic layer formed on the diamond-like carbon film.
